(19) United States
(12) Patent Application Publication
(10) Pub. No.: US 2021/0175079 A1
(43) Pub. Date: Jun. 10, 2021

(54) PLATING METHOD, PLATING APPARATUS AND RECORDING MEDIUM

(71) Applicant: Tokyo Electron Limited, Tokyo (JP)

(72) Inventor: Mitsuaki Iwashita, Kikuchi-gun, Kumamoto (JP)

(21) Appl. No.: 16/769,714

(22) PCT Filed: Nov. 22, 2018
(86) PCT No.: PCT/JP2018/043098

§ 371 Date: Jun. 4, 2020

(30) Foreign Application Priority Data
Dec. 6, 2017 (JP) 2017-234445

(51) Int. Cl. H01L 21/033; C23C 18/16; C23C 18/18; C23C 18/36; H01L 21/02

(52) U.S. Cl. CPC H01L 21/0337; C23C 18/1603; C23C 18/163; C23C 18/1689; C23C 18/1642; H01L 21/0335; C23C 18/36; H01L 21/0217; H01L 21/02282; H01L 21/02304; H01L 21/0332; C23C 18/1893

(57) ABSTRACT

On a surface of a substrate having a plateable material portion and a non-plateable material portion, a polymer compound, which selectively reacts with an OH end group of the non-plateable material portion, is supplied. By performing a catalyst imparting processing on the substrate on which the polymer compound is supplied, a catalyst is selectively imparted to the plateable material portion. Further, by performing a plating processing on the substrate, a plating layer is selectively formed on the plateable material portion. Before or after forming the plating layer, the polymer compound on the substrate is removed.

### TECHNICAL FIELD

The various aspects and embodiments described herein pertain generally to a plating method, a plating apparatus and a recording medium.

### BACKGROUND

Recently, as miniaturization and three-dimensionalization of semiconductor devices progress, it is required to improve processing accuracy of etching when processing the semiconductor devices. As one way to improve the processing accuracy of the etching, it is required to improve accuracy of a hard mask (HM) for dry etching which is formed on a substrate.

### PRIOR ART DOCUMENT

Patent Document 1: Japanese Patent Laid-open Publication No. 2009-249679

In general, however, there are many restrictions for a material of the hard mask. For example, the material of the hard mask needs to have high adhesivity to a substrate and a resist, needs to have high resistance against a heat treatment and an etching processing, and, also, needs to be easily removed. For the reason, conventionally, only a limited material such as SiN (silicon nitride) or TiN (titanium nitride) has been used as the material of the hard mask.

In view of this, the present inventors have examined applying a catalyst such as Pd onto a substrate having thereon a film of SiO (silicon oxide) or the like and a film of SiN (silicon nitride) or the like to thereby apply the catalyst only onto the SiN film selectively; and forming a plating layer only on the SiN film by using this catalyst. In this case, since the plating layer formed on the SiN film can be used as a hard mask, it is possible to select various kinds of materials as the plating layer.

In this case, it is desirable that the plating layer is formed on the basis of the catalyst on the SiN film in the state that the catalyst is selectively applied on the SiN film and no catalyst is left on the SiO film at all. Actually, however, the catalyst such as the Pd also remains on the SiO film to some extent, and selectivity regarding the application of the catalyst may not be sufficient. In such a case, there is a concern that the plating layer is also precipitated on the SiO film on which the plating layer is not supposed to be formed.

In view of the foregoing, exemplary embodiments provide a plating method and a plating apparatus capable of applying a catalyst to a plateable material portion with high selectivity, and a recording medium therefor.

### SUMMARY

In one exemplary embodiment, a plating method comprises preparing a substrate having, on a surface thereof, a plateable material portion and a non-plateable material portion having an OH end group; supplying a polymer compound, which selectively reacts with the OH end group of the non-plateable material portion, onto the substrate; imparting a catalyst to the plateable material portion selectively by performing a catalyst imparting processing on the substrate on which the polymer compound is supplied; forming a plating layer on the plateable material portion selectively by performing a plating processing on the substrate; and removing the polymer compound on the substrate before or after the forming of the plating layer.

In another exemplary embodiment, a plating apparatus comprises a substrate holder configured to hold a substrate having, on a surface thereof, a plateable material portion and a non-plateable material portion having an OH end group; a polymer compound supply configured to supply a polymer compound, which selectively reacts with the OH end group of the non-plateable material portion, onto the substrate; a catalyst imparting device configured to impart a catalyst to the plateable material portion selectively by performing a catalyst imparting processing on the substrate on which the polymer compound is supplied; a plating liquid supply configured to supply a plating liquid onto the substrate to thereby form a plating layer on the plateable material portion selectively; and a polymer compound removing device configured to remove the polymer compound on the substrate.

In still another exemplary embodiment, a computer-readable recording medium stores thereon computer-executable instructions that, in response to execution, cause the plating apparatus to perform the plating method.

According to the exemplary embodiments, it is possible to apply the catalyst to the plateable material portion with high selectivity.

### BRIEF DESCRIPTION OF THE DRAWINGS

FIG. 1 is a schematic plan view illustrating a plating apparatus and a plating unit belonging to the plating apparatus.

FIG. 2 is a schematic cross sectional view illustrating a configuration of a plating device belonging to the plating unit shown in FIG. 1.

FIG. 3 is a schematic cross sectional view illustrating a structure of a substrate on which a plating layer is to be formed by a plating method according to an exemplary embodiment.

FIG. 4A to FIG. 4E are schematic cross sectional views illustrating a producing method for the substrate on which the plating layer is to be formed by the plating method according to the present exemplary embodiment.

FIG. 5 is a flowchart illustrating the plating method according to the present exemplary embodiment.

FIG. 6A to FIG. 6C are schematic cross sectional views illustrating the plating method according to the present exemplary embodiment.

FIG. 7A to FIG. 7C are schematic cross sectional views illustrating a method of processing the substrate on which the plating layer is formed by the plating method according to the present exemplary embodiment.

FIG. 8A to FIG. 8C are schematic diagrams illustrating an operation in which a catalyst adheres to a surface of the substrate.

FIG. 9 is a cross sectional view illustrating a configuration of a plating device according to a modification example (modification example 1).

FIG. 10 is a flowchart illustrating a plating method according to the modification example (modification example 1).

FIG. 11 is a flowchart illustrating a plating method according to another modification example (modification example 2).

### DETAILED DESCRIPTION

Hereinafter, exemplary embodiments will be described with reference to the accompanying drawings.

<Configuration of Plating Apparatus>

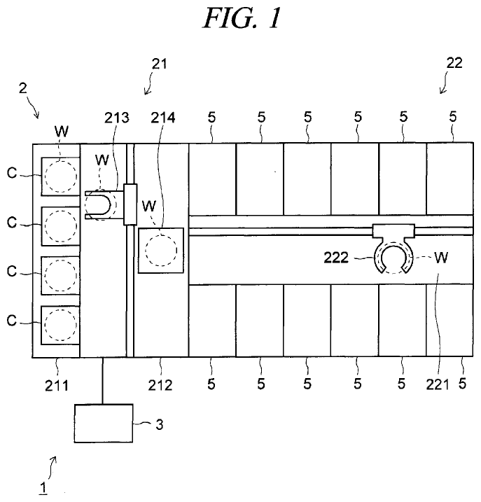

Referring to FIG. 1, a configuration of a plating apparatus according to an exemplary embodiment will be explained. FIG. 1 is a schematic diagram illustrating the configuration of the plating apparatus according to the exemplary embodiment.

As depicted in FIG. 1, a plating apparatus 1 according to the exemplary embodiment is equipped with a plating unit 2 and a controller 3 configured to control an operation of the plating unit 2.

The plating unit 2 is configured to perform various processings on a substrate. The various processings performed by the plating unit 2 will be discussed later.

The controller 3 is implemented by, for example, a computer, and includes an operation controller and a storage unit. The operation controller is implemented by, for example, a CPU (Central Processing Unit) and is configured to control an operation of the plating unit 2 by reading and executing the programs stored in the storage unit. The storage unit is implemented by a memory device such as, but not limited to, a RAM (Random Access Memory), a ROM (Read Only Memory) or a hard disk, and stores thereon programs for controlling various processings performed in the plating unit 2. Further, the programs may be recorded in a computer-readable recording medium, or may be installed from the recording medium to the storage unit. The computer-readable recording medium may be, for example, a hard disc (HD), a flexible disc (FD), a compact disc (CD), a magnet optical disc (MO), or a memory card. Stored in the recording medium is a program which, when executed by a computer for controlling an operation of the plating apparatus 1, allows the computer to control the plating apparatus 1 to perform a plating method to be described later.

<Configuration of Plating Unit>

Referring to FIG. 1, a configuration of the plating unit 2 will be discussed. FIG. 1 is a schematic plan view illustrating the configuration of the plating unit 2.

The plating unit 2 includes a carry-in/out station 21 and a processing station 22 which is provided adjacent to the carry-in/out station 21.

The carry-in/out station 21 is equipped with a placing section 211 and a transfer section 212 which is provided adjacent to the placing section 211.

In the placing section 211, transfer containers (hereinafter, referred to as “carriers C”) for accommodating therein a plurality of substrates W horizontally are placed.

The transfer section 212 is equipped with a transfer device 213 and a delivery unit 214. The transfer device 213 is provided with a holding mechanism configured to hold a substrate W and is configured to be movable horizontally and vertically and pivotable around a vertical axis.

The processing station 22 includes plating devices 5. In the present exemplary embodiment, the number of the plating devices 5 belonging to the processing station 22 is two or more. However, only one plating device 5 may be provided. The plating devices 5 are arranged at both sides of a transfer path 221 which extends in a preset direction.

A transfer device 222 is provided in the transfer path 221. The transfer device 222 is equipped with a holding mechanism configured to hold the substrate W and is configured to be movable horizontally and vertically and pivotable around a vertical axis.

In the plating unit 2, the transfer device 213 of the carry-in/out station 21 is configured to transfer the substrate W between the carrier C and the delivery unit 214. To elaborate, the transfer device 213 takes out the substrate W from the carrier C which is placed in the placing section 211, and places the substrate W in the delivery unit 214. Further, the transfer device 213 takes out the substrate W which is placed in the delivery unit 214 by the transfer device 222 of the processing station 22, and accommodates the substrate W back into the carrier C on the placing section 211.

In the plating unit 2, the transfer device 222 of the processing station 22 is configured to transfer the substrate W between the delivery unit 214 and the plating device 5 and between the plating device 5 and the delivery unit 214. To elaborate, the transfer device 222 takes out the substrate W which is placed in the delivery unit 214 and then carries the substrate W into the plating device 5. Further, the transfer device 222 takes out the substrate W from the plating unit 5 and places the substrate W in the delivery unit 214.

<Configuration of Plating Device>

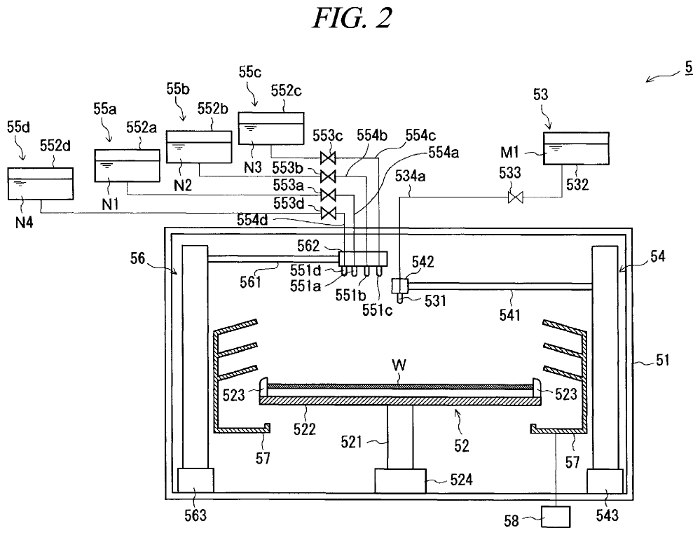

Now, referring to FIG. 2, a configuration of the plating device 5 will be explained. FIG. 2 is a schematic cross sectional view illustrating the configuration of the plating device 5.

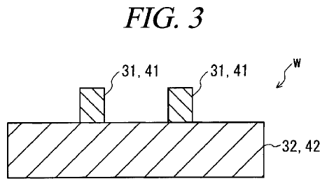

The plating device 5 is configured to perform a plating processing on a substrate W having, on a surface thereof, a non-plateable material portion 31 and a plateable material portion 32, and to form a plating layer 35 selectively on the plateable material portion 32 (refer to FIG. 3 to FIG. 7C to be described later). A substrate processing performed by the plating device 5 includes a catalyst imparting processing and an electroless plating processing at least. However, the substrate processing may further include other processings in addition to the catalyst imparting processing and the plating processing.

The plating device 5 is configured to perform the aforementioned substrate processing including the electroless plating processing. The plating device 5 includes a chamber 51; a substrate holder 52 provided within the chamber 51 and configured to hold the substrate W; and a plating liquid supply 53 configured to supply a plating liquid M1 to the substrate W held by the substrate holder 52.

The substrate holder 52 includes a rotation shaft 521 extending in a vertical direction within the chamber 51; a turntable 522 provided at an upper end portion of the rotation shaft 521; a chuck 523 provided on an outer peripheral portion of a top surface of the turntable 522 and configured to support an edge portion of the substrate W; and a driving unit 524 configured to rotate the rotation shaft 521.

The substrate W is supported by the chuck 523 to be horizontally held by the turntable 522 while being slightly spaced apart from the top surface of the turntable 522. In the present exemplary embodiment, a mechanism of holding the substrate W by the substrate holder 52 is of a so-called mechanical chuck type in which the edge portion of the substrate W is held by the chuck 523 which is configured to be movable. However, a so-called vacuum chuck type in which a rear surface of the substrate W is vacuum-attracted may be used instead.

A base end portion of the rotation shaft 521 is rotatably supported by the driving unit 524, and a leading end portion of the rotation shaft 521 sustains the turntable 522 horizontally. If the rotation shaft 521 is rotated, the turntable 522 placed on the upper end portion of the rotation shaft 521 is rotated, and, as a result, the substrate W which is held by the turntable 522 with the chuck 523 is also rotated.

The plating liquid supply 53 is equipped with a nozzle 531 configured to discharge the plating liquid M1 onto the substrate W held by the substrate holder 52; and a plating liquid source 532 configured to supply the plating liquid M1 to the nozzle 531. The plating liquid M1 is stored in a tank of the plating liquid source 532, and the plating liquid M1 is supplied into the nozzle 531 from the plating liquid source 532 through a supply passageway 534 which is equipped with a flow rate controller such as a valve 533.

The plating liquid M1 is a plating liquid for an autocatalytic (reduction) electroless plating. The plating liquid M1 contains a metal ion such as a cobalt (Co) ion, a nickel (Ni) ion, or a tungsten (W) ion; and a reducing agent such as hypophosphorous acid or dimethylamineborane. Further, in the autocatalytic (reduction) electroless plating, the metal ion in the plating liquid M1 is reduced by electrons emitted in an oxidation reaction of the reducing agent in the plating liquid M1 to be precipitated as a metal, so that a metal film (plating film) is formed. The plating liquid M1 may further contain an additive or the like. The metal film (plating film) formed by the plating processing with the plating liquid M1 may be, by way of non-limiting example, CoB, CoP, CoWP, CoWB, CoWBP, NiWB, NiB, NiWP, NiWBP, or the like. P (phosphorus) in the metal film (plating film) is originated from the reducing agent (e.g., hypophosphorous acid) containing P, and B (boron) in the plating film is originated from the reducing agent (e.g., dimethylamineborane) containing B.

The nozzle 531 is connected to a nozzle moving device 54. The nozzle moving device 54 is configured to drive the nozzle 531. The nozzle moving device 54 includes an arm 541; a moving body 542 which is configured to be movable along the arm 541 and has a driving mechanism embedded therein; and a rotating/elevating device 543 configured to rotate and move the arm 541 up and down. The nozzle 531 is provided at the moving body 542. The nozzle moving device 54 is capable of moving the nozzle 531 between a position above a center of the substrate W held by the substrate holder 52 and a position above a periphery of the substrate W, and is also capable of moving the nozzle 531 up to a stand-by position outside a cup 57 to be described later when viewed from the top.

Within the chamber 51, there are arranged a catalyst solution supply (catalyst imparting device) 55a, a cleaning liquid supply 55b, a rinse liquid supply 55c, and a polymer compound supply 55d configured to supply a catalyst solution N1, a cleaning liquid N2, a rinse liquid N3, and a polymer compound N4 in a liquid state onto the substrate W held by the substrate holder 52, respectively.

The catalyst solution supply (catalyst imparting device) 55a includes a nozzle 551a configured to discharge the catalyst solution N1 onto the substrate W held by the substrate holder 52; and a catalyst solution source 552a configured to supply the catalyst solution N1 to the nozzle 551a. The catalyst solution N1 is stored in a tank of the catalyst solution source 552a, and the catalyst solution N1 is supplied to the nozzle 551a from the catalyst solution source 552a through a supply passageway 554a which is provided with a flow rate controller such as a valve 553a.

The cleaning liquid supply 55b includes a nozzle 551b configured to discharge the cleaning liquid N2 onto the substrate W held by the substrate holder 52; and a cleaning liquid source 552b configured to supply the cleaning liquid N2 to the nozzle 551b. The cleaning liquid N2 is stored in a tank of the cleaning liquid source 552b, and the cleaning liquid N2 is supplied to the nozzle 551b from the cleaning liquid source 552b through a supply passageway 554b which is provided with a flow rate controller such as a valve 553b.

The rinse liquid supply 55c includes a nozzle 551c configured to discharge the rinse liquid N3 onto the substrate W held by the substrate holder 52; and a rinse liquid source 552c configured to supply the rinse liquid N3 to the nozzle 551c. The rinse liquid N3 is stored in a tank of the rinse liquid source 552c, and the rinse liquid N3 is supplied to the nozzle 551c from the rinse liquid source 552c through a supply passageway 554c which is provided with a flow rate controller such as a valve 553c.

The polymer compound supply 55d includes a nozzle 551d configured to discharge the polymer compound N4 in the liquid state onto the substrate W held by the substrate holder 52; and a polymer compound source 552d configured to supply the polymer compound N4 to the nozzle 551d. The polymer compound N4 in the liquid state is stored in a tank of the polymer compound source 552d, and the polymer compound N4 is supplied to the nozzle 551d from the polymer compound source 552d through a supply passageway 554d which is provided with a flow rate controller such as a valve 553d.

The catalyst solution N1 contains a metal ion having catalytic activity to the oxidation reaction of the reducing agent in the plating liquid M1. In the electroless plating processing, to allow the precipitation of the metal ion in the plating liquid M1 to be begun, an initial film surface (that is, a plating target surface of the substrate) need to have sufficient catalytic activity to the oxidation reaction of the reducing agent in the plating liquid M1. By way of non-limiting example, such a catalyst may include, iron group elements (Fe, Co, Ni), platinum group elements (Ru, Rh, Pd, Os, Ir, Pt), Cu, Ag or Au. A metal film having the catalytic activity is formed through a replacement reaction. In the replacement reaction, a component forming the plating target surface of the substrate serves as a reducing agent, and the metal ion (for example, a palladium (Pd) ion) in the catalyst solution N1 is reduced to be precipitated on the plating target surface of the substrate. Further, the catalyst solution N1 may contain a metal catalyst in the form of nanoparticles. To elaborate, the catalyst solution N1 may include the metal catalyst in the form of nanoparticles, a dispersant, and an aqueous solution. This metal catalyst in the form of nanoparticles may be, by way of non-limiting example, palladium (Pd) in the form of nanoparticles. Further, the dispersant serves to allow the metal catalyst in the form of nanoparticles to be easily dispersed in the catalyst solution N1.

As an example of the cleaning liquid N2, an organic acid such as a formic acid, malic acid, a succinic acid, a citric acid or a malonic acid, or hydrofluoric acid (DHF) (aqueous solution of hydrogen fluoride) diluted to the extent that it does not corrode the plating target surface of the substrate may be used.

As an example of the rinse liquid N3, pure water may be used.

The polymer compound N4 is a liquid which selectively reacts with an OH end group of a non-plateable material portion 31 (to be described later) of the substrate W. This polymer compound N4 has a function of making the catalyst in the catalyst solution N1 difficult to adsorb into the non-plateable material portion 31 of the substrate W. This polymer compound N4 is a polymer compound having a weight-average molecular weight (Mw) equal to or larger than 1000, and, specifically, one containing an acryl-based polymer or polyglycerin may be used. Particularly, to allow the polymer compound N4 on the substrate W to be easily removed by the rinse liquid N3, it is desirable to use a water-soluble polymer compound as the polymer compound N4.

The plating device 5 includes a nozzle moving device 56 configured to move the nozzles 551a to 551d. The nozzle moving device 56 is equipped with an arm 561; a moving body 562 which is configured to be movable along the arm 561 and has a moving mechanism embedded therein; and a rotating/elevating device 563 configured to rotate and move the arm 561 up and down. The nozzles 551a to 551d are provided at the moving body 562. The nozzle moving device 56 is capable of moving the nozzles 551a to 551d between a position above the central portion of the substrate W held by the substrate holder 52 and a position above the peripheral portion of the substrate W, and also capable of moving the nozzles 551a to 551d up to a stand-by position outside the cup 57 to be described later when viewed from the top. In the present exemplary embodiment, though the nozzles 551a to 551d are held by the common arm, they may be configured to be held by different arms respectively and moved independently.

The cup 57 is disposed around the substrate holder 52. The cup 57 is configured to receive various kinds of processing liquids (e.g., the catalyst solution, the plating liquid, the cleaning liquid, the rinse liquid, the polymer compound, etc.) scattered from the substrate W and drain the received processing liquids to the outside of the chamber 51. The cup 57 is equipped with an elevating device 58 configured to move the cup 57 up and down.

<Structure of Substrate>

Now, a structure of the substrate on which the plating layer is to be formed by the plating method according to the present exemplary embodiment will be explained.

As depicted in FIG. 3, the substrate W on which the plating layer 35 is to be formed has the non-plateable material portion 31 and the plateable material portion 32 respectively formed on the surface thereof. There is no specific limitation in the structure of the non-plateable material portion 31 and the plateable material portion 32 as long as they are exposed at the surface of the substrate W. In the present exemplary embodiment, the substrate W includes a base member 42 made of the plateable material portion 32; and a core member 41 which is protruded from the base member 42 and is made of the non-plateable material portion 31 having a pattern shape.

The non-plateable material portion 31 is a region where the plating metal is not precipitated and the plating layer 35 is not formed when the plating processing according to the exemplary embodiment is performed. The non-plateable material portion 31 has the OH end group and is made of a material having, for example, SiO₂ as a main component.

The plateable material portion 32 is a region where the plating metal is precipitated and the plating layer 35 is formed when the plating processing according to the exemplary embodiment is performed. The plateable material portion 32 has a NHₓ end group and is made of a material having, by way of example, but not limitation, SiN as a main component.

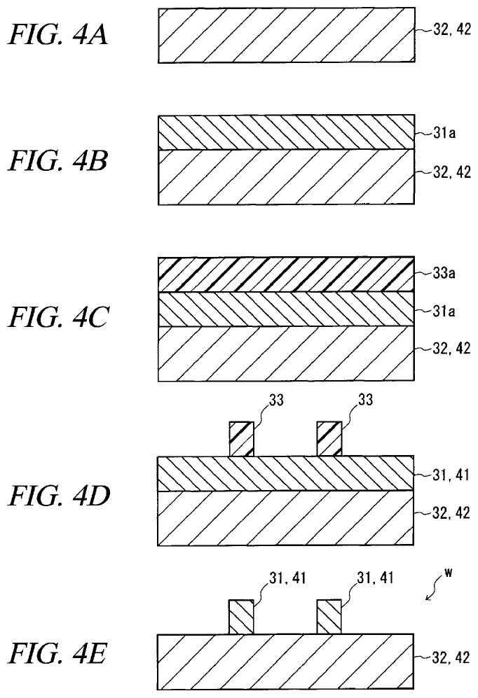

Now, a method of producing the substrate W shown in FIG. 3 will be explained with reference to FIG. 4A to FIG. 4E. To produce the substrate W shown in FIG. 3, the base member 42 made of the plateable material portion 32 is first prepared, as illustrated in FIG. 4A.

Thereafter, as depicted in FIG. 4B, a film of a material 31a, which forms the non-plateable material portion 31, is formed by a CVD method or a PVD method on the entire surface of the base member 42 which is made of the plateable material portion 32. The material 31a is composed of, for example, the material containing SiO₂ as the main component.

Subsequently, as illustrated in FIG. 4C, a photosensitive resist 33a is coated on the entire surface of the material 31a forming the non-plateable material portion 31, and then, is dried. Then, by exposing the photosensitive resist 33a through a photo mask and developing it, a resist film 33 having a required pattern is formed, as shown in FIG. 4D.

Afterwards, as depicted in FIG. 4E, the material 31a is dry-etched by using the resist film 33 as a mask. As a result, the core member 41 made of the non-plateable material portion 31 is patterned to have the substantially same shape as the pattern shape of the resist film 33. Then, by removing the resist film 33, there is obtained the substrate W having the non-plateable material portion 31 and the plateable material portion 32 formed on the surface thereof.

<Plating Method>

Now, the plating method using the plating apparatus 1 will be discussed. The plating method performed by plating apparatus 1 includes a plating processing upon the aforementioned substrate W. The plating processing is performed by the plating device 5. An operation of the plating device 5 is controlled by the controller 3.

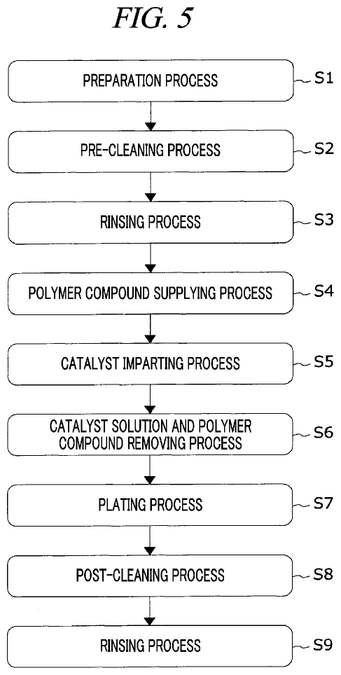

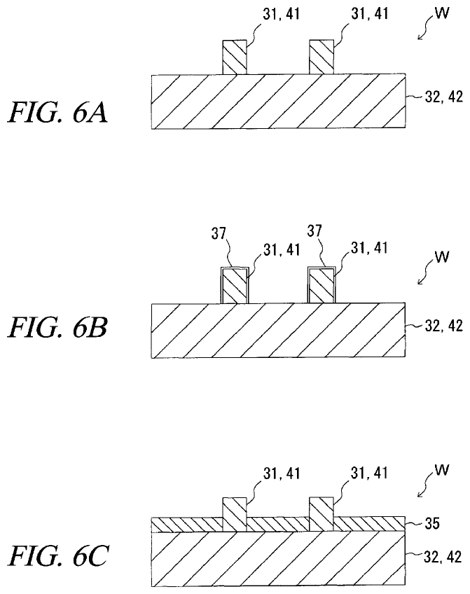

First, the substrate W having the non-plateable material portion 31 and the plateable material portion 32 formed on the surface thereof is prepared by performing the above-described method of FIG. 4A to FIG. 4E (preparation process: process 51 of FIG. 5) (see FIG. 6A).

The prepared substrate W is then carried into the plating device 5 to be held by the substrate holder 52 (see FIG. 2). In the meanwhile, the controller 3 controls the elevating device 58 to move the cup 57 down to a preset position. Then, the controller 3 controls the transfer device 222 to place the substrate W on the substrate holder 52. The substrate W is horizontally placed on the turntable 522 with its periphery portion held by the chuck 523.

Then, the substrate W held by the substrate holder 52 is subjected to a cleaning processing (pre-cleaning process: process S2 of FIG. 5). At this time, while controlling the driving unit 524 to rotate the substrate W held by the substrate holder 52 at a preset speed, the controller 3 controls the cleaning liquid supply 55b to locate the nozzle 551b at a position above the substrate W and to supply the cleaning liquid N2 onto the substrate W from the nozzle 551b. The cleaning liquid N2 supplied onto the substrate W is diffused on the surface of the substrate W by a centrifugal force which is caused by the rotation of the substrate W. As a result, a deposit or the like adhering to the substrate W is removed from the substrate W. The cleaning liquid N2 scattered from the substrate W is drained through the cup 57.

Subsequently, the substrate W after being cleaned is subjected to a rinsing processing (rinsing process: process S3 of FIG. 5). At this time, while controlling the driving unit 524 to rotate the substrate W held by the substrate holder 52 at a preset speed, the controller 3 controls the rinse liquid supply 55c to locate the nozzle 551c at a position above the substrate W and to supply the rinse liquid N3 onto the substrate W from the nozzle 551c. The rinse liquid N3 supplied onto the substrate W is diffused on the surface of the substrate W by the centrifugal force which is caused by the rotation of the substrate W. As a result, the cleaning liquid N2 remaining on the substrate W is washed away. The rinse liquid N3 scattered from the substrate W is drained through the cup 57.

Thereafter, by supplying the polymer compound N4 in the liquid state onto the substrate W held by the substrate holder 52, a polymer film is formed on the substrate W (polymer compound supplying process: process S4 of FIG. 5). At this time, while controlling the driving unit 524 to rotate the substrate W held by the substrate holder 52 at a preset speed, the controller 3 controls the polymer compound supply 55d to locate the nozzle 551d at a position above the substrate W and to supply the polymer compound N4 onto the substrate W from the nozzle 551d. By way of non-limiting example, an acryl-based polymer or polyglycerin is used as the polymer compound N4. The polymer compound N4 in the liquid state supplied onto the substrate W is diffused on the surface of the substrate W by the centrifugal force which is caused by the rotation of the substrate W. This polymer compound N4 selectively reacts with the OH end group of the non-plateable material portion 31 to produce a polymer film 37. Thus, the polymer film 37 is thinly formed selectively on a surface of the non-plateable material portion 31 of the substrate W (see FIG. 6B). This polymer film 37 serves to suppress adhesion of the catalyst to the non-plateable material portion 31 in a catalyst imparting process. The polymer compound N4 scattered from the substrate W is drained through the cup 57.

Subsequently, the substrate W having the polymer film 37 formed thereon is subjected to a catalyst imparting processing (catalyst imparting process: process S5 of FIG. 5). At this time, while controlling the driving unit 524 to rotate the substrate W held by the substrate holder 52 at a preset speed, the controller 3 controls the catalyst solution supply 55a to locate the nozzle 551a at a position above the substrate W and to supply the catalyst solution N1 onto the substrate W from the nozzle 551a. The catalyst solution N1 supplied onto the substrate W is diffused on the surface of the substrate W by the centrifugal force which is caused by the rotation of the substrate W. The catalyst solution N1 scattered from the substrate W is drained through the cup 57.

Accordingly, the catalyst is imparted to the plateable material portion 32 of the substrate W selectively, and a metal film having catalytic activity is formed on the plateable material portion 32. Meanwhile, the catalyst is not substantially imparted to the non-plateable material portion 31 of the substrate W, which has the SiO₂ as the main component, and the metal film having catalytic activity is not formed on this non-plateable material portion 31. As a non-limiting example of such a metal having catalytic activity, iron group elements (Fe, Co, Ni), platinum group elements (Ru, Rh, Pd, Os, Ir, Pt), Cu, Ag or Au may be used. These metals have high adsorption property with respect to the material (e.g., SiN) forming the plateable material portion 32, whereas the metals are difficult to adsorb to the material (e.g., SiO₂) forming the non-plateable material portion 31. Thus, by using these metals, it is possible to allow the plating metal to be selectively precipitated on the plateable material portion 32. Specifically, the catalyst solution N1 may include the Pd catalyst in the form of nanoparticles, the dispersant, and the aqueous solution. Furthermore, the catalyst solution N1 may further include an adsorption accelerator which accelerates the adsorption of the aforementioned metals having catalytic activity.

Further, in the present exemplary embodiment, the non-plateable material portion 31 is selectively covered with the polymer film 37 of the polymer compound N4. Accordingly, the adhesion of the catalyst to the non-plateable material portion 31 is suppressed. Meanwhile, since the plateable material portion 32 is not covered with the polymer film 37, the catalyst is adsorbed to the plateable material portion 32 securely.

Thereafter, the substrate W having the plateable material portion 32 to which the catalyst is selectively imparted is subjected to a cleaning processing (catalyst solution and polymer compound removing process: process S6 of FIG. 5). At this time, while controlling the driving unit 524 to rotate the substrate W held by the substrate holder 52 at a preset speed, the controller 3 controls the rinse liquid supply 55c to locate the nozzle 551c at a position above the substrate W and to supply the rinse liquid N3 onto the substrate W from the nozzle 551c. The rinse liquid N3 supplied onto the substrate W is diffused on the surface of the substrate W by the centrifugal force which is caused by the rotation of the substrate W. Accordingly, the catalyst solution N1 remaining on the substrate W is washed away. Concurrently, the polymer film 37 formed by the water-soluble polymer compound N4 is also removed by the rinse liquid N3. The rinse liquid N3 and the polymer compound N4 scattered from the substrate W are drained through the cup 57. Here, the substrate W may be cleaned by using alkaline water or an acidic cleaning liquid such as hydrofluoric acid (DHF), instead of the rinse liquid N3.

Subsequently, the substrate W is subjected to a plating processing, and the plating is selectively performed on the plateable material portion 32 (plating process: process S7 of FIG. 5). Accordingly, the plating layer 35 is formed on the plateable material portion 32 (see FIG. 6C). The plating layer 35 is formed at a portion of the plateable material portion 32 which is not covered with the non-plateable material portion 31. At this time, while controlling the driving unit 524 to rotate the substrate W held by the substrate holder 52 at a preset speed or while maintaining the substrate W held by the substrate holder 52 stopped, the controller 3 controls the plating liquid supply 53 to locate the nozzle 531 at a position above the substrate W and to supply the plating liquid M1 onto the substrate W from the nozzle 531. As a result, the plating metal is selectively precipitated on the plateable material portion 32 of the substrate W (specifically, on the metal film having catalytic activity formed on the surface of the plateable material portion 32), so that the plating layer 35 is formed. Meanwhile, since the metal film having catalytic activity is not formed on the non-plateable material portion 31 of the substrate W, no plating metal is precipitated on the non-plateable material portion 31, so that no plating layer 35 is formed thereon

Upon the completion of the plating processing as described above, the substrate W held by the substrate holder 52 is subjected to a cleaning processing (post-cleaning process: process S8 of FIG. 5). At this time, while controlling the driving unit 524 to rotate the substrate W held by the substrate holder 52 at a preset speed, the controller 3 controls the cleaning liquid supply 55b to locate the nozzle 551b at the position above the substrate W and to supply the cleaning liquid N2 onto the substrate W from the nozzle 551b. The cleaning liquid N2 supplied onto the substrate W is diffused on the surface of the substrate W by the centrifugal force which is caused by the rotation of the substrate W. Accordingly, an abnormal plating film or a reaction by-product adhering to the substrate W is removed from the substrate W. The cleaning liquid N2 scattered from the substrate W is drained through the cup 57.

Then, while controlling the driving unit 524 to rotate the substrate W held by the substrate holder 52 at a preset speed, the controller 3 controls the rinse liquid supply 55c to locate the nozzle 551c at the position above the substrate W and to supply the rinse liquid N3 onto the substrate W from the nozzle 551c (rinsing process: process S9 of FIG. 5). Accordingly, the plating liquid M1, the cleaning liquid N2 and the rinse liquid N3 on the substrate W are scattered from the substrate W by the centrifugal force which is caused by the rotation of the substrate W, and are drained through the cup 57.

Thereafter, the substrate W on which the plating layer 35 is formed is carried out of the plating device 5. At this time, the controller 3 controls the transfer device 222 to take out the substrate W from the plating device 5 and place the taken-out substrate W in the delivery unit 214. Then, the controller 3 controls the transfer device 213 to take out the substrate W placed in the delivery unit 214 and to carry the substrate W into the carrier C in the placing section 211.

Then, the substrate W is etched by using the plating layer 35 as a hard mask.

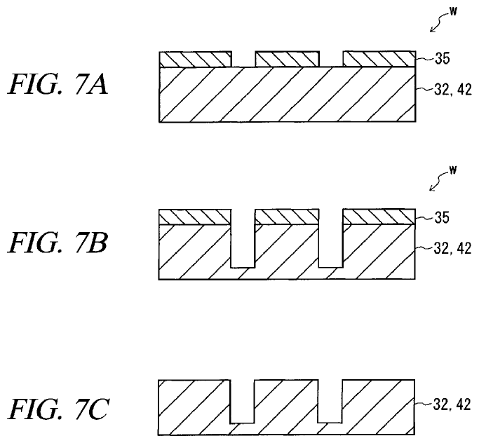

In this case, the non-plateable material portion 31 is first removed selectively from the substrate W which is taken out of the plating device 5 (FIG. 7A). Meanwhile, the plating layer 35 formed on the plateable material portion 32 remains without being removed.

Subsequently, as shown in FIG. 7B, the base member 42 made of the plateable material portion 32 is dry-etched by using the plating layer 35 as the hard mask. Accordingly, the portion of the base member 42 which is not covered with the plating layer 35 is etched to a preset depth, and recesses having a pattern shape are formed.

Afterwards, by removing the plating layer 35 through a wet cleaning method, the base member 42 provided with the recesses having the pattern shape is obtained, as illustrated in FIG. 7C. Since the plating layer 35 can be removed by the wet cleaning method, it is easy to remove the plating layer 35. An acidic solvent is employed as a chemical liquid used in this wet cleaning method.

As described above, according to the present exemplary embodiment, the polymer compound N4 which reacts with the OH end group of the non-plateable material portion 31 selectively is supplied onto the substrate W. As a result, the non-plateable material portion 31 can be covered with the polymer film 37 selectively. Thereafter, by performing the catalyst imparting processing on the substrate W, the catalyst is selectively imparted to the plateable material portion 32. At this time, the catalyst does not adhere to the non-plateable material portion 31 which is covered with the polymer film 37. In this way, since the catalyst can be imparted to the plateable material portion 32 with high selectivity, it is possible to suppress the plating layer from being formed on the non-plateable material portion 31 on which the plating layer is not intended to be formed.

The reason why the catalyst can be imparted to the plateable material portion 32 with high selectivity with the polymer film 37 of the polymer compound N4 is deemed to be as follows.

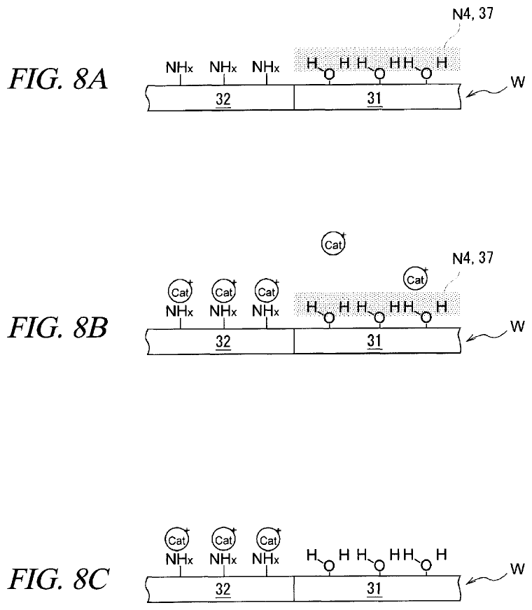

That is, when the polymer compound N4 is supplied onto the substrate W (process S4 of FIG. 5), the polymer compound N4 selectively reacts with the OH end group of the non-plateable material portion 31, as shown in FIG. 8A. As a result, the polymer compound N4 forms the polymer film 37 and covers the non-plateable material portion 31. Meanwhile, since no OH end group exists on the plateable material portion 32, the polymer film 37 does not substantially cover the plateable material portion 32.

Subsequently, a catalyst Cat is imparted to the substrate W (process S5 of FIG. 5), as shown in FIG. 8B. At this time, the catalyst Cat reacts with the NHₓ end group of the plateable material portion 32, and the catalyst Cat is adsorbed to the plateable material portion 32. Meanwhile, since the non-plateable material portion 31 is covered with the polymer film 37, the adsorption of the catalyst Cat is hampered. Thus, the catalyst Cat is not substantially adsorbed to the non-plateable material portion 31.

Thereafter, by performing the cleaning processing on the substrate W to remove the catalyst solution and the polymer film 37 (process S6 of FIG. 5), the polymer film 37 covering the non-plateable material portion 31 is washed away, as depicted in FIG. 8C. Meanwhile, the catalyst Cat adsorbed to the plateable material portion 32 is not substantially washed away by the rinse liquid N3 or the like, but remains adsorbed to the plateable material portion 32. In this way, by supplying the polymer compound N4 onto the substrate W, it is possible to impart the catalyst to the plateable material portion 32 with high selectivity.

### MODIFICATION EXAMPLES

Now, various modification examples of the present exemplary embodiment will be explained. Further, in the various drawings illustrating the following modification examples, the same parts as those described in the above exemplary embodiment will be assigned same reference numerals. Further, in the following, redundant description upon common features will be omitted, while focusing on distinctive features from the above-described exemplary embodiment.

### Modification Example 1

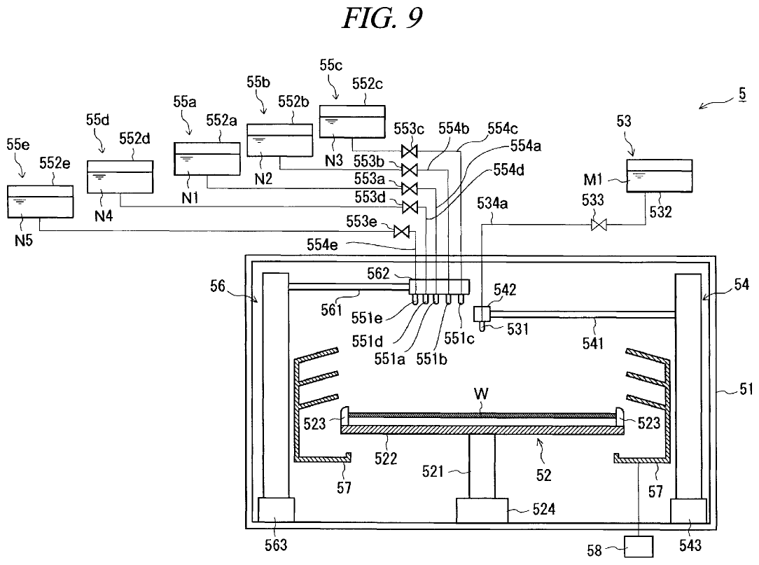

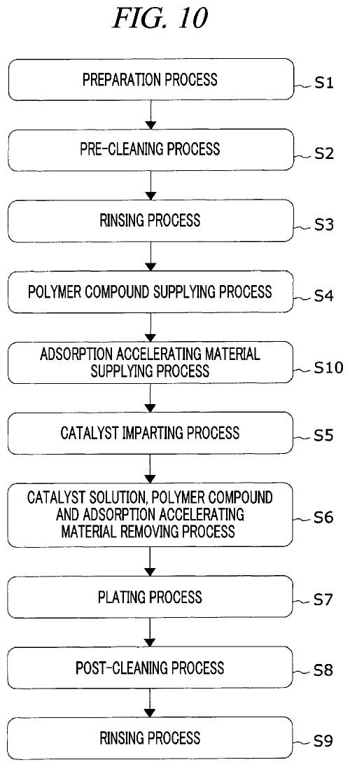

FIG. 9 and FIG. 10 are diagrams illustrating a modification example (modification example 1) of the present exemplary embodiment. As depicted in FIG. 9, the plating device 5 may be further equipped with an adsorption accelerating material supply 55e configured to supply an adsorption accelerating material N5 onto the substrate W held by the substrate holder 52. This adsorption accelerating material supply 55e includes a nozzle 551e configured to discharge the adsorption accelerating material N5 onto the substrate W held by the substrate holder 52; and an adsorption accelerating material source 552e configured to supply the adsorption accelerating material N5 to the nozzle 551e. The adsorption accelerating material N5 in a liquid state is stored in a tank of the adsorption accelerating material source 552e, and the adsorption accelerating material N5 is supplied into the nozzle 551e from the adsorption accelerating material source 552e through a supply passageway 554e which is equipped with a flow rate controller such as a valve 553e. The nozzle 551e is held by the arm 561 to be movable along with the nozzles 551a to 551d.

The adsorption accelerating material N5 is a liquid which selectively reacts with the NHₓ end group of the plateable material portion 32 of the substrate W. This adsorption accelerating material N5 has a function of allowing the catalyst in the catalyst solution N1 to be more easily adsorbed into the plateable material portion 32. By way of non-limiting example, one including a thiol compound or a triazole compound may be used as the adsorption accelerating material N5.

In this case, a process of supplying the adsorption accelerating material N5 onto the substrate W (adsorption accelerating material supplying process: process S10) is performed before a catalyst imparting process (process S5) and after the polymer compound supplying process (process S4), as shown in FIG. 10.

In this adsorption accelerating material supplying process (process S10), the adsorption accelerating material N5 is supplied onto the substrate W. At this time, while controlling the driving unit 524 to rotate the substrate W held by the substrate holder 52 at a preset speed, the controller 3 controls the adsorption accelerating material supply 55e to locate the nozzle 551e at a position above the substrate W and to supply the adsorption accelerating material N5 onto the substrate W from the nozzle 551e. The adsorption accelerating material N5 supplied onto the substrate W is diffused on the surface of the substrate W by a centrifugal force which is caused by the rotation of the substrate W. This adsorption accelerating material N5 selectively reacts with the NHₓ end group of the plateable material portion 32 to produce a film of the adsorption accelerating material N5. As a result, a film of the adsorption accelerating material N5 is formed on the surface of the plateable material portion 32 of the substrate W selectively. This adsorption accelerating material N5 serves to accelerate the adhesion of the catalyst to the plateable material portion 32 in the catalyst imparting process. The adsorption accelerating material N5 scattered from the substrate W is drained through the cup 57.

Then, the substrate W having the film of the adsorption accelerating material N5 formed on the plateable material portion 32 and the polymer film 37 formed on the non-plateable material portion 31 is subjected to the catalyst imparting processing (catalyst imparting process: process S5 of FIG. 5), the same as in the above-described exemplary embodiment. Thereafter, in a catalyst solution, polymer compound and adsorption accelerating material removing process (process S6), by discharging the rinse liquid N3 onto the substrate W, the catalyst solution N1, the polymer film 37 and the adsorption accelerating material N5 are washed away to be removed by the rinse liquid N3.

### Modification Example 2

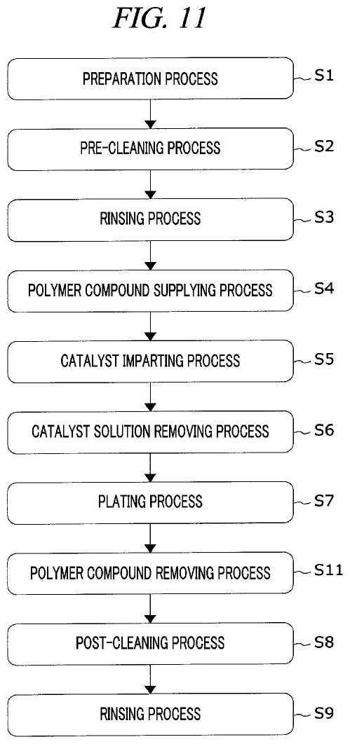

FIG. 11 is a diagram illustrating another modification example (modification example 2) of the present exemplary embodiment. The present exemplary embodiment has been described for the example where the catalyst solution and polymer compound removing process (process S6) of removing the polymer compound N4 on the substrate W is performed before the plating process (process S7) of forming the plating layer 35. As depicted in FIG. 11, however, a polymer compound removing process (process S11) may be performed after the plating process (process S7). By way of example, in case that the polymer film 37 of the polymer compound N4 is made of a material which is not removable by the rinse liquid N3, the non-plateable material portion 31 may be kept covered with the polymer film 37 in the plating process (process S7). Then, upon the completion of the plating process (process S7), the polymer compound N4 is removed by being washed away by a cleaning liquid capable of dissolving the polymer compound N4. In such a case, the precipitation of the plating metal on the non-plateable material portion 31 can be suppressed more securely. Furthermore, in the plating method shown in FIG. 11 as well, an adsorption accelerating material supplying process (process S10) may be performed after the polymer compound supplying process (process S4) and before the catalyst imparting process (process S5).

### Modification Example 3

The present exemplary embodiment has been described for the example where the catalyst imparting process (process S5) is performed after the polymer compound supplying process (process S4). However, the exemplary embodiment is not limited thereto, and a preliminary polymer compound removing process of removing a small amount of the polymer film 37 adhering to the plateable material portion 32 on the substrate W may be performed before the catalyst imparting process (process S5) and after the polymer compound supplying process (process S4). There may be assumed a case where the polymer film 37 adheres on the plateable material portion 32 for some reasons. In such a case, by supplying a small amount of, for example, a rinse liquid or a chemical liquid onto the substrate W to the extent that the polymer film 37 covering the non-plateable material portion 31 is not completely removed, the unnecessary polymer film 37 on the plateable material portion 32 can be washed away to be removed.

Although the various exemplary embodiments have been described so far, those exemplary embodiments are not limiting and can be modified in various ways without departing from the technical conception and essence of the present disclosure. Further, the constituent components described in the above exemplary embodiments may be combined appropriately to produce various other embodiments, and may be partially deleted in various ways. Further, the constituent components in the different exemplary embodiments may be appropriately combined.

1. A plating method, comprising:
preparing a substrate having, on a surface thereof, a plateable material portion and a non-plateable material portion having an OH end group;
supplying a polymer compound, which selectively reacts with the OH end group of the non-plateable material portion, onto the substrate;
imparting a catalyst to the plateable material portion selectively by performing a catalyst imparting processing on the substrate on which the polymer compound is supplied;
forming a plating layer on the plateable material portion selectively by performing a plating processing on the substrate; and
removing the polymer compound on the substrate before or after the forming of the plating layer.

2. The plating method of claim 1,
wherein the polymer compound is an acryl-based polymer or polyglycerin.

3. The plating method of claim 1,
wherein the plateable material portion has a NHₓ end group, and
the plating method further comprises supplying an adsorption accelerating material, which selectively reacts with the NHₓ end group of the plateable material portion, onto the substrate after the supplying of the polymer compound and before the imparting of the catalyst.

4. The plating method of claim 3,
wherein the adsorption accelerating material is a thiol compound or a triazole compound.

5. A plating apparatus, comprising:
a substrate holder configured to hold a substrate having, on a surface thereof, a plateable material portion and a non-plateable material portion having an OH end group;
a polymer compound supply configured to supply a polymer compound, which selectively reacts with the OH end group of the non-plateable material portion, onto the substrate;
a catalyst imparting device configured to impart a catalyst to the plateable material portion selectively by performing a catalyst imparting processing on the substrate on which the polymer compound is supplied;
a plating liquid supply configured to supply a plating liquid onto the substrate to thereby form a plating layer on the plateable material portion selectively; and
a polymer compound removing device configured to remove the polymer compound on the substrate.

6. The plating apparatus of claim 5,
wherein the polymer compound is an acryl-based polymer or polyglycerin.

7. The plating apparatus of claim 5,
wherein the plateable material portion has a NHₓ end group, and
the plating apparatus further comprises an adsorption accelerating material supply configured to supply an adsorption accelerating material, which selectively reacts with the NHₓ end group of the plateable material portion, onto the substrate.

8. The plating apparatus of claim 7,
wherein the adsorption accelerating material is a thiol compound or a triazole compound.

9. A computer-readable recording medium having stored thereon computer-executable instructions that, in response to execution, cause a plating apparatus to perform a plating method as claimed in claim 1.
